(19) United States
(12) Patent Application Publication
(10) Pub. No.: US 2018/0306884 A1
(43) Pub. Date: Oct. 25, 2018

(54) ACCELERATED DYNAMIC MAGNETIC RESONANCE IMAGING USING LOW RANK MATRIX COMPLETION

(71) Applicant: Mayo Foundation for Medical Education and Research, Rochester, MN (US)

(72) Inventors: Joshua D. Trzasko, Rochester, MN (US); Eric G. Stinson, Rochester, MN (US); Stephen J. Riederer, Rochester, MN (US)

(21) Appl. No.: 15/958,425

(22) Filed: Apr. 20, 2018

Related U.S. Application Data
(60) Provisional application No. 62/488,155, filed on Apr. 21, 2017.

(51) Int. Cl. G01R 33/563; G01R 33/56; G01R 33/48

(52) U.S. Cl. CPC G01R 33/56308; G01R 33/5601; G01R 33/56545; G01R 33/4824; G01R 33/5635

(57) ABSTRACT

Accelerated dynamic magnetic resonance imaging (“MRI”) methods in which low-rank matrix completion is implemented as a pre-processing step to fill undersampled accelerated k-space while retaining both spatial and temporal resolution are described. The undersampled k-space data are acquired using multilevel sampling, in which both uniform undersampling and non-uniform undersampling are combined to achieve high temporal resolution while retaining spatial resolution.

### CROSS-REFERENCE TO RELATED APPLICATIONS

This application claims the benefit of U.S. Provisional Patent Application Ser. No. 62/488,155, filed on Apr. 21, 2017, and entitled “ACCELERATED DYNAMIC MAGNETIC RESONANCE IMAGING USING LOW RANK MATRIX COMPLETION,” which is herein incorporated by reference in its entirety.

### STATEMENT REGARDING FEDERALLY SPONSORED RESEARCH

This invention was made with government support under EB017840 awarded by the National Institutes of Health. The government has certain rights in the invention.

### BACKGROUND

Dynamic magnetic resonance imaging (“MRI”) is useful for a number of applications, including cardiac imaging, contrast-enhanced magnetic resonance angiography, and perfusion imaging with dynamic contrast-enhanced MRI (“DCE-MRI”) or dynamic susceptibility-enhanced MRI (“DSC-MRI”). To obtain the necessary high spatial and temporal resolution for these imaging applications, undersampling is typically used. When multilevel sampling of uniform and non-uniform undersampling are combined, an image update time of less than five seconds can be achieved while retaining spatial resolution.

Methods to account for the non-uniform sampling include “sample-and-hold view sharing” (“SHVS”), where samples from neighboring time frames are shared to enhance image quality and spatial resolution (by increasing the coverage of k-space) at the expense of temporal resolution; or using the raw data to retain temporal resolution at the expense of spatial resolution. Other techniques use a sparse penalty to reconstruct undersampled images before a model-based or data driven reconstruction. Alternatively, a full regression-type reconstruction can be performed to account for multilevel sampling at the expense of reconstruction time.

Thus, there remains a need for accelerated dynamic imaging using multilevel sampling that retains both high spatial and temporal resolution.

### SUMMARY OF THE DISCLOSURE

The present disclosure addresses the aforementioned drawbacks by providing a method for producing an image of a subject from k-space data acquired with a magnetic resonance imaging (MRI) system. Multilevel k-space data acquired from a subject using an MRI system are provided to a computer system. The multilevel k-space data includes uniformly undersampled k-space data and non-uniformly undersampled k-space data. A uniformly undersampled k-space data set is generated from the multilevel k-space data by processing the multilevel k-space data using a low-rank matrix completion. One or more images of the subject are reconstructed from the uniformly undersampled k-space data set.

The foregoing and other aspects and advantages of the present disclosure will appear from the following description. In the description, reference is made to the accompanying drawings that form a part hereof, and in which there is shown by way of illustration a preferred embodiment. This embodiment does not necessarily represent the full scope of the invention, however, and reference is therefore made to the claims and herein for interpreting the scope of the invention.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a flowchart setting forth the steps of an example method for accelerated dynamic magnetic resonance imaging (“MRI”) using multilevel sampling and a low-rank matrix completion preprocessing.

FIG. 2A illustrates an example multilevel data acquisition scheme.

FIG. 2B is an example of a union of three different non-uniform sampling patterns used to sample a peripheral region of k-space in the example multilevel data acquisition scheme of FIG. 2A.

FIG. 3 is a block diagram of an example image reconstruction unit implemented with a hardware processor and a memory, which can implement the methods described in the present disclosure.

FIG. 4 is a block diagram of an example MRI system that can implement the methods described in the present disclosure.

### DETAILED DESCRIPTION

Described here are methods for accelerated dynamic magnetic resonance imaging (“MRI”) in which low-rank matrix completion is implemented as a pre-processing step to fill undersampled accelerated k-space while retaining both spatial and temporal resolution. The undersampled k-space data are acquired using multilevel sampling, in which both uniform undersampling and non-uniform undersampling are combined to achieve high temporal resolution while retaining spatial resolution.

An image can be reconstructed from multilevel undersampled k-space data by solving a computationally expensive full regression problem, or by breaking the reconstruction problem into two separate steps for each sampling operator. In the methods described in the present disclosure, the latter approach is taken using a low-rank matrix completion as a preprocessing step to complete the non-uniform sampling operator before SENSE reconstruction unfolds the effects of the uniform sampling operator.

The full signal model for a time-resolved, multi-coil acquisition with multilevel sampling can be described by,

Gδₜ=(I⊗ΦₜF)SMXδₜ+Zδₜ (1);

where G is the received multi-coil signal with dimensions KₜC×T; I is an identify matrix with dimensions C×C; Φₜ is a non-uniform sampling operator at time, t, with dimensions Kₜ×R; F is a uniform sampling operator, which may be a uniform SENSE-type sampling operator, with dimensions R×N; S are the coil sensitivities with dimensions NC×N; M is a spatial support mask with dimensions N×M; X is the desired image series with dimensions M×T; Z is zero-mean, Gaussian noise with dimensions KₜCxT; δₜ is Kronecker's delta; and ⊗ is Kronecker's product.

Eqn. (1) can be used to efficiently solve a full regression problem, but the methods described in the present disclosure can provide improved efficiency by preprocessing the data in the uniformly undersampled space before performing SENSE unfolding, which may be conventional SENSE unfolding. This preprocessing is performed under the assumption that a priori knowledge of the final image also informs the folded image, the undersampled k-space, or both. The signal model for the preprocessing step in k-space can be given by,

Gδₜ=(I⊗ΦₜF)Yδₜ+Zδₜ (2);

where Yδₜ is now the multi-coil uniformly undersampled k-space signal. Solving for Y accounts for the preprocessing step, followed by a SENSE reconstruction, which may be a standard SENSE reconstruction.

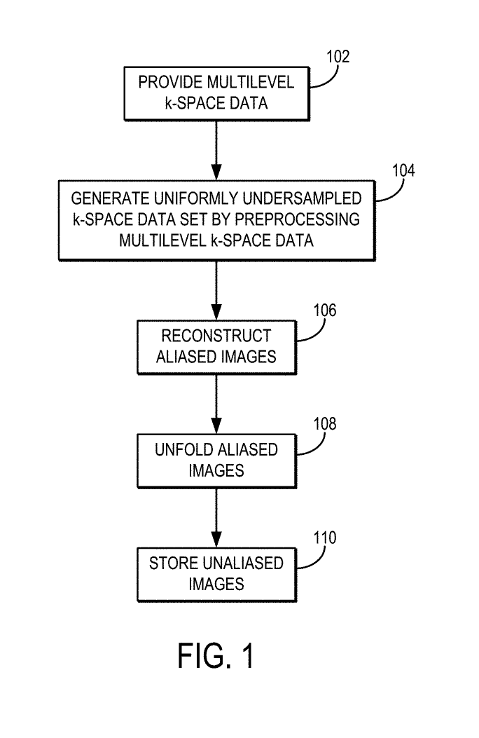

Referring now to FIG. 1, a flowchart is illustrated as setting forth the steps of an example method for reconstructing images from multilevel undersampled k-space data acquired with an MRI system. The method includes providing k-space data to a computer system for processing and reconstruction, as indicated at step 102. Providing the k-space data can include retrieving previously acquired k-space data from a memory or other data storage, or can include acquiring the k-space data with an MRI system that communicates the acquired k-space data to the computer system, which may form a part of the MRI system. The provided k-space data are generally multilevel undersampled k-space data acquired using multiple different RF coils, such as an RF coil array, and are generally acquired over a period of time such that the k-space data represent a dynamic time series of images.

As mentioned above, the k-space data are acquired using multilevel sampling (e.g., both uniform sampling and non-uniform sampling). The uniform sampling can be implemented using a uniform sampling operator, which may be a SENSE-type operator or other suitable uniform sampling operator. The non-uniform sampling can be implemented using a suitable non-uniform sampling operator. In some instances, the non-uniform sampling operator can include a random or pseudorandom sampling operator. In some embodiments, the non-uniformly sampled k-space data can be acquired in an interleaved fashion with uniformly sampled k-space data. As one non-limiting example, the non-uniformly sampled k-space data can include a number of pseudorandom k-space data sets that are acquired in an alternating periodic fashion through time.

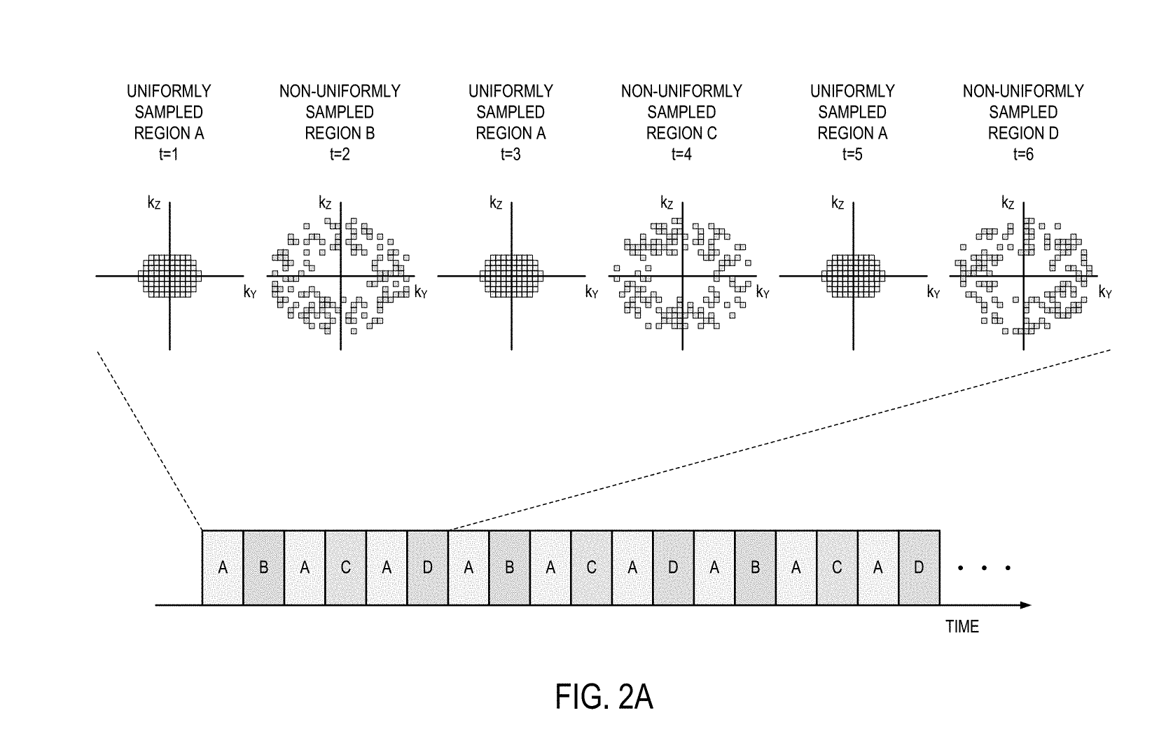

One non-limiting example of an acquisition that implements a multilevel sampling scheme is shown in FIG. 2A This acquisition is implemented by alternating between a uniform sampling of a central region of k-space and one of three different non-uniform samplings of the peripheral region of k-space. As shown in FIG. 2B, in this example, the union of the non-uniform sampling patterns results in a uniform sampling of the peripheral region of k-space. In other implementations, however, the union of the non-uniform sampling patterns need not result in a uniform sampling of the peripheral region of k-space. In some implementations, the uniform and non-uniform sampling patterns can at least partially overlap, or as shown in FIGS. 2A and 2B, can be designed so no overlap exists between the different sampling patterns. Similarly, in some implementations some or all of the non-uniform sampling patterns can partially overlap, or not overlap at all.

Referring again to FIG. 1, the k-space data are then preprocessed using a low-rank matrix completion penalty as uniform undersampling in k-space, as indicated at step 104, which results in object folding in the image domain, but does not change the low-rank nature of a dynamic time series. The regression used for the preprocessing can have the form,

$$\hat{Y} = arg { min}_{Y} \{ {\sum }_{t = 1}^{T} {‖ G {δ}_{t} - ( I ⊗ {Φ}_{t} ) Y {δ}_{t} ‖}_{2}^{2} + λ P ( Y ) \} ; \qquad ( 3 )$$

where P(Y) is a measure of matrix rank, which may be a direct measure, a surrogate measure, or other suitable measure. As one non-limiting example, the measure of matrix rank can be a nuclear norm. As another non-limiting example, the measure of matrix rank can be a Schatten p-norm. As another non-limiting example, the measure of matrix rank can be a log-determinant. In one non-limiting example, the low-rank matrix completion can be performed on the Casorati form of the acquired k-space data, G, in an iterative manner. For instance, the preprocessing can proceed in an iterative thresholding manner where after each iteration a singular value thresholding and data fidelity enforcement via data replacement are implemented. In some other implementations, the regression can be computed using an iteratively reweighted least squares algorithm. As still another example, the regression can be computed using a dual iterative scheme or a primal-dual iterative scheme. Examples of primal-dual iterative schemes that can be implemented are described in co-pending PCT Application No. PCT/US18/26417, which is herein incorporated by reference in its entirety.

The preprocessed data, Ŷ, are then Fourier transformed, as indicated at step 106, to generate aliased images. The aliased images are then processed using a parallel imaging reconstruction method to generate unaliased images, as indicated at step 108. In some embodiments, the parallel imaging reconstruction can be an image-domain based method, such as an image-domain sensitivity encoded reconstruction. An example of such a reconstruction is a SENSE reconstruction. In other embodiments, the parallel imaging reconstruction can be a Fourier-domain based method, such as a Fourier-domain auto-calibrating reconstruction. An example of such a reconstruction is a GRAPPA reconstruction. The unaliased images are then stored for later use, or displayed to a user, as indicated at step 110. It will be appreciated by those skilled in the art that parallel image reconstruction methods that operate in the k-space domain can also be implemented, at which point the unaliased images are reconstructed based on such methods being applied to the preprocessed data.

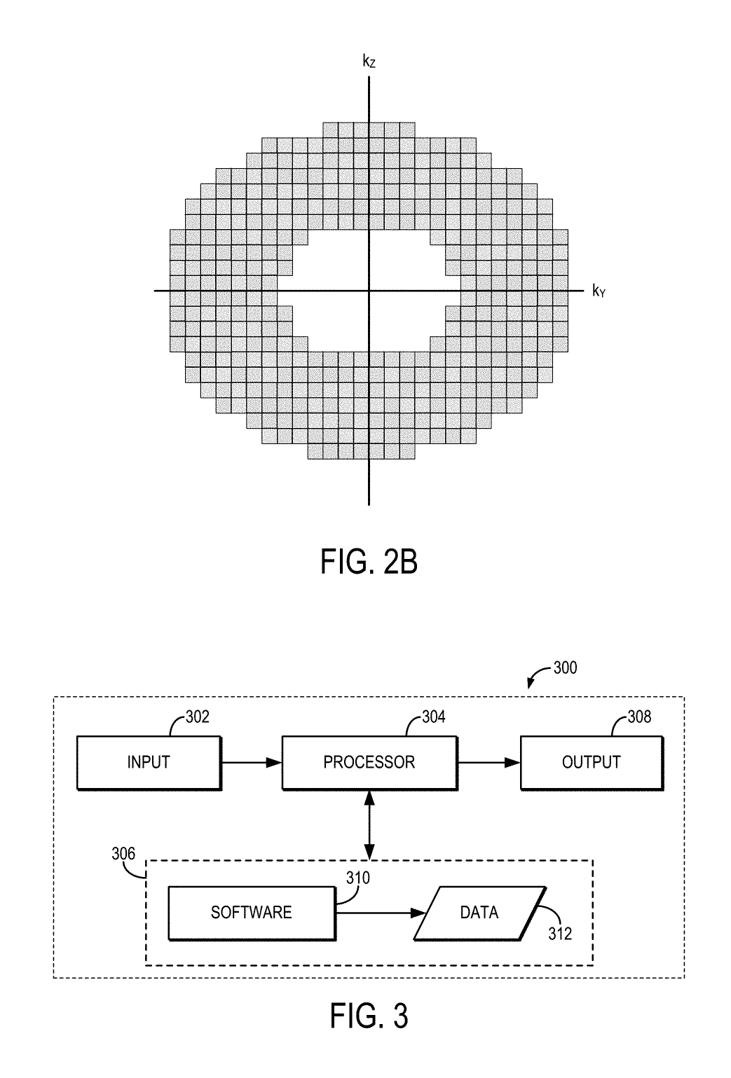

Referring now to FIG. 3, a block diagram of an example of an image reconstruction unit 300 that can perform the methods described in the present disclosure is shown. The image reconstruction unit 300 is generally implemented with a hardware processor 304 and a memory 306.

The image reconstruction unit 300 includes an input 302, at least one hardware processor 304, a memory 306, and an output 308. The image reconstruction unit 300 can also include any suitable device for reading computer-readable storage media. The image reconstruction unit 300 may be implemented, in some examples, a workstation, a notebook computer, a tablet device, a mobile device, a multimedia device, a network server, a mainframe, or any other general-purpose or application-specific computing device. The image reconstruction unit 300 may operate autonomously or semi-autonomously, or may read executable software instructions from the memory 306 or a computer-readable medium (e.g., a hard drive, a CD-ROM, flash memory), or may receive instructions via the input 302 from a user, or any another source logically connected to a computer or device, such as another networked computer or server. In general, the image reconstruction unit 300 is programmed or otherwise configured to implement the methods and algorithms described above.

The input 302 may take any suitable shape or form, as desired, for operation of the image reconstruction unit 300, including the ability for selecting, entering, or otherwise specifying parameters consistent with performing tasks, processing data, or operating the image reconstruction unit 300. In some aspects, the input 302 may be configured to receive data, such as multilevel sampled k-space data acquired with an MRI system. Such data may be processed as described above to reconstruct an image, which may be a two-dimensional or three-dimensional image. In addition, the input 302 may also be configured to receive any other data or information considered useful for reconstructing an image from the acquired multilevel sampled k-space data using the methods described above.

Among the processing tasks for operating the image reconstruction unit 300, the at least one hardware processor 304 may also be configured to carry out any number of post-processing steps on data received by way of the input 302.

The memory 306 may contain software 310 and data 312, such as data acquired with a measurement system, and may be configured for storage and retrieval of processed information, instructions, and data to be processed by the at least one hardware processor 304. In some aspects, the software 310 may contain instructions directed to reconstructing images from the multilevel sampled k-space data acquired with an MRI system.

In addition, the output 308 may take any shape or form, as desired, and may be configured for displaying, in addition to other desired information, reconstructed images.

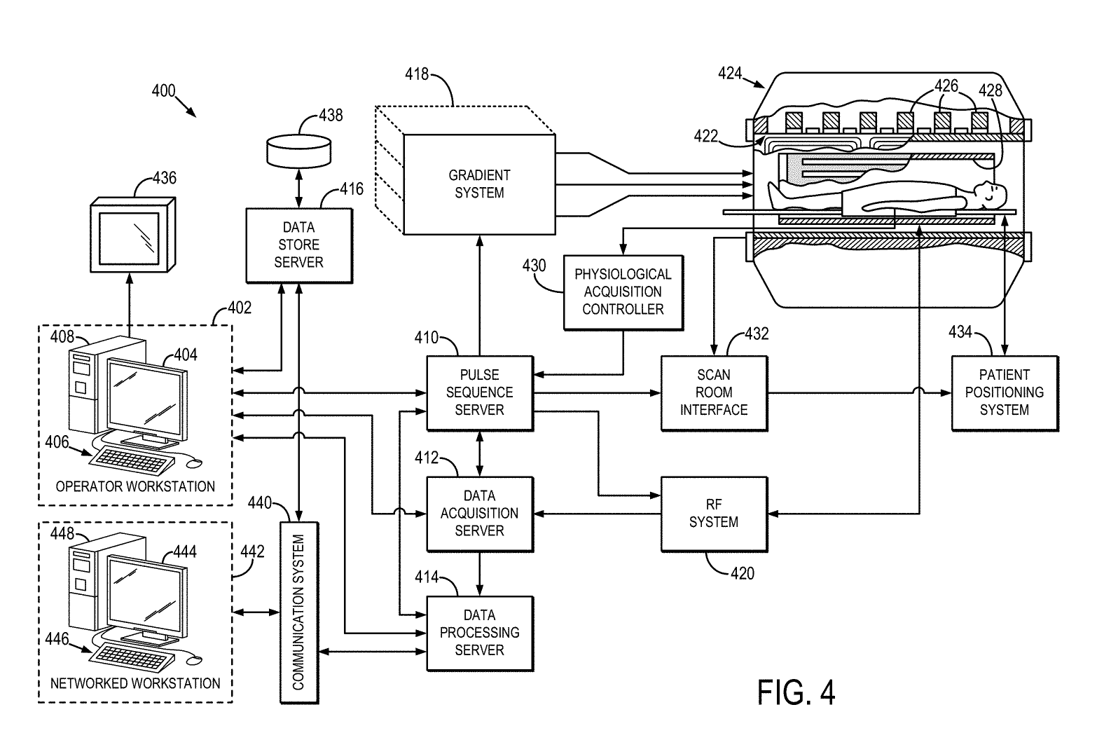

Referring particularly now to FIG. 4, an example of an MRI system 400 that can implement the methods described here is illustrated. The MRI system 400 includes an operator workstation 402 that may include a display 404, one or more input devices 406 (e.g., a keyboard, a mouse), and a processor 408. The processor 408 may include a commercially available programmable machine running a commercially available operating system. The operator workstation 402 provides an operator interface that facilitates entering scan parameters into the MRI system 400. The operator workstation 402 may be coupled to different servers, including, for example, a pulse sequence server 410, a data acquisition server 412, a data processing server 414, and a data store server 416. The operator workstation 402 and the servers 410, 412, 414, and 416 may be connected via a communication system 440, which may include wired or wireless network connections.

The pulse sequence server 410 functions in response to instructions provided by the operator workstation 402 to operate a gradient system 418 and a radiofrequency (“RF”) system 420. Gradient waveforms for performing a prescribed scan are produced and applied to the gradient system 418, which then excites gradient coils in an assembly 422 to produce the magnetic field gradients Gₓ, G_{y}, and G_{z} that are used for spatially encoding magnetic resonance signals. The gradient coil assembly 422 forms part of a magnet assembly 424 that includes a polarizing magnet 426 and a whole-body RF coil 428.

RF waveforms are applied by the RF system 420 to the RF coil 428, or a separate local coil to perform the prescribed magnetic resonance pulse sequence. Responsive magnetic resonance signals detected by the RF coil 428, or a separate local coil, are received by the RF system 420. The responsive magnetic resonance signals may be amplified, demodulated, filtered, and digitized under direction of commands produced by the pulse sequence server 410. The RF system 420 includes an RF transmitter for producing a wide variety of RF pulses used in MRI pulse sequences. The RF transmitter is responsive to the prescribed scan and direction from the pulse sequence server 410 to produce RF pulses of the desired frequency, phase, and pulse amplitude waveform. The generated RF pulses may be applied to the whole-body RF coil 428 or to one or more local coils or coil arrays.

The RF system 420 also includes one or more RF receiver channels. An RF receiver channel includes an RF preamplifier that amplifies the magnetic resonance signal received by the coil 428 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

M=\sqrt{I²+Q²} (4);

and the phase of the received magnetic resonance signal may also be determined according to the following relationship:

$$ϕ = {tan}^{\_ 1} ( \frac{Q}{I} ) . \qquad ( 5 )$$

The pulse sequence server 410 may receive patient data from a physiological acquisition controller 430. By way of example, the physiological acquisition controller 430 may receive signals from a number of different sensors connected to the patient, including electrocardiograph (“ECG”) signals from electrodes, or respiratory signals from a respiratory bellows or other respiratory monitoring devices. These signals may be used by the pulse sequence server 410 to synchronize, or “gate,” the performance of the scan with the subject's heart beat or respiration.

The pulse sequence server 410 may also connect to a scan room interface circuit 432 that receives signals from various sensors associated with the condition of the patient and the magnet system. Through the scan room interface circuit 432, a patient positioning system 434 can receive commands to move the patient to desired positions during the scan.

The digitized magnetic resonance signal samples produced by the RF system 420 are received by the data acquisition server 412. The data acquisition server 412 operates in response to instructions downloaded from the operator workstation 402 to receive the real-time magnetic resonance data and provide buffer storage, so that data is not lost by data overrun. In some scans, the data acquisition server 412 passes the acquired magnetic resonance data to the data processor server 414. In scans that require information derived from acquired magnetic resonance data to control the further performance of the scan, the data acquisition server 412 may be programmed to produce such information and convey it to the pulse sequence server 410. For example, during pre-scans, magnetic resonance data may be acquired and used to calibrate the pulse sequence performed by the pulse sequence server 410. As another example, navigator signals may be acquired and used to adjust the operating parameters of the RF system 420 or the gradient system 418, or to control the view order in which k-space is sampled. In still another example, the data acquisition server 412 may also process magnetic resonance signals used to detect the arrival of a contrast agent in a magnetic resonance angiography (“MRA”) scan. For example, the data acquisition server 412 may acquire magnetic resonance data and processes it in real-time to produce information that is used to control the scan.

The data processing server 414 receives magnetic resonance data from the data acquisition server 412 and processes the magnetic resonance data in accordance with instructions provided by the operator workstation 402. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, generating functional magnetic resonance images, or calculating motion or flow images.

Images reconstructed by the data processing server 414 are conveyed back to the operator workstation 402 for storage. Real-time images may be stored in a data base memory cache, from which they may be output to operator display 402 or a display 436. Batch mode images or selected real time images may be stored in a host database on disc storage 438. When such images have been reconstructed and transferred to storage, the data processing server 414 may notify the data store server 416 on the operator workstation 402. The operator workstation 402 may be used by an operator to archive the images, produce films, or send the images via a network to other facilities.

The MRI system 400 may also include one or more networked workstations 442. For example, a networked workstation 442 may include a display 444, one or more input devices 446 (e.g., a keyboard, a mouse), and a processor 448. The networked workstation 442 may be located within the same facility as the operator workstation 402, or in a different facility, such as a different healthcare institution or clinic.

The networked workstation 442 may gain remote access to the data processing server 414 or data store server 416 via the communication system 440. Accordingly, multiple networked workstations 442 may have access to the data processing server 414 and the data store server 416. In this manner, magnetic resonance data, reconstructed images, or other data may be exchanged between the data processing server 414 or the data store server 416 and the networked workstations 442, such that the data or images may be remotely processed by a networked workstation 442.

The present disclosure has described one or more preferred embodiments, and it should be appreciated that many equivalents, alternatives, variations, and modifications, aside from those expressly stated, are possible and within the scope of the invention.

1. A method for producing an image of a subject from k-space data acquired with a magnetic resonance imaging (MRI) system, the steps of the method comprising:
(a) providing to a computer system, multilevel k-space data acquired from a subject using an MRI system, wherein the multilevel k-space data comprises uniformly undersampled k-space data and non-uniformly undersampled k-space data;
(b) generating a uniformly undersampled k-space data set by processing the multilevel k-space data using a low-rank matrix completion implemented with a hardware processor and memory of a computer system; and
(c) reconstructing one or more images of the subject from the uniformly undersampled k-space data set.

2. The method as recited in claim 1, wherein generating the uniformly undersampled k-space data set comprises performing a regression on the acquired multilevel k-space data to fill portions of the non-uniformly sampled k-space data in the multilevel k-space data.

3. The method as recited in claim 2, wherein the low-rank matrix completion comprises optimizing a cost function that includes a measure of matrix rank.

4. The method as recited in claim 3, wherein the measure of matrix rank is one of a direct measure of matrix rank or a surrogate measure of matrix rank.

5. The method as recited in claim 3, wherein the measure of matrix rank includes one of a nuclear norm, a Schatten p-norm, or a log-determinant.

6. The method as recited in claim 2, wherein the regression comprises the low-rank matrix completion performed on the multilevel k-space data.

7. The method as recited in claim 6, wherein the regression is computed using an iterative thresholding algorithm.

8. The method as recited in claim 7, wherein each iteration of the iterative thresholding algorithm comprises a singular value thresholding step and a data fidelity enforcement step.

9. The method as recited in claim 8, wherein the data fidelity enforcement step includes a data replacement step.

10. The method as recited in claim 6, wherein the regression is computed using an iterative algorithm that implements one of a dual iterative scheme or a primal-dual iterative scheme.

11. The method as recited in claim 6, wherein the regression is computed using an iteratively reweighted least squares algorithm.

12. The method as recited in claim 1, wherein step (c) includes computing a Fourier transform of the uniformly undersampled k-space data set to generate one or more aliased images and processing the one or more aliased images to remove aliasing artifacts in order to generate the one or more reconstructed images.

13. The method as recited in claim 12, wherein processing the one or more aliased images comprises performing a parallel imaging reconstruction.

14. The method as recited in claim 13, wherein the parallel imaging reconstruction is an image-domain sensitivity encoded reconstruction.

15. The method as recited in claim 13, wherein the parallel imaging reconstruction is a Fourier domain auto-calibrating reconstruction.

16. The method as recited in claim 1, wherein the multilevel k-space data comprises a plurality of data frames that uniformly sample a first region of k-space, and a plurality of data frames that non-uniformly sample a second region of k-space.

17. The method as recited in claim 16, wherein the first region of k-space is a central region of k-space and the second region of k-space is a peripheral region of k-space.

18. The method as recited in claim 17, wherein the first region of k-space and the second region of k-space do not overlap.

19. The method as recited in claim 17, wherein the plurality of data frames that non-uniformly sample the second region of k-space comprises a plurality of different non-uniformly sampled k-space data sets, wherein each of the plurality of different non-uniformly sampled k-space data sets samples a different portion of the second region of k-space.

20. The method as recited in claim 17, wherein the multilevel k-space data represent a time series of image frames, and wherein the multilevel k-space data are acquired by alternating between acquiring a data frame that uniformly samples the first region of k-space and a data frames that non-uniformly samples the second region of k-space.

21. The method as recited in claim 1, wherein the uniformly undersampled k-space data in the multilevel k-space data uniformly sample a first region of k-space and the non-uniformly undersampled k-space data in the multilevel k-space data sample a second region of k-space.

22. The method as recited in claim 21, wherein the first region of k-space is a central region of k-space and the second region of k-space is a peripheral region of k-space.

23. The method as recited in claim 22, wherein the first region of k-space and the second region of k-space do not overlap.
